(19) United States
(12) Patent Application Publication
(10) Pub. No.: US 2025/0244804 A1
(43) Pub. Date: Jul. 31, 2025

(54) COMPRESSION BRIDGE AND COOLER HAVING THE SAME

(71) Applicant: ARCTIC (HK) Limited, Hong Kong (HK)

(72) Inventor: Magnus Huber, Hong Kong (HK)

(73) Assignee: ARCTIC (HK) Limited, Hong Kong (HK)

(21) Appl. No.: 19/040,016

(22) Filed: Jan. 29, 2025

Related U.S. Application Data
(63) Continuation of application No. 63/626,225, filed on Jan. 29, 2024.

(51) Int. Cl. G06F 1/20; H05K 7/20

(52) U.S. Cl. CPC G06F 1/20; H05K 7/20254; G06F 2200/201

(57) ABSTRACT

An improved cooler is provided that includes a clip or bridge for centralizing pressure in a central portion of a cooler plate to deform the plate convexly in order to improve contact between the cooler plate and an IHS of a CPU or other device to be cooled.

### CROSS-REFERENCE TO RELATED APPLICATIONS

This application claims priority to U.S. Provisional Patent Application No. 63/626,225, filed on Jan. 29, 2024, and titled COMPRESSION BRIDGE AND COOLER HAVING THE SAME; the entire contents of which are hereby incorporated herein by reference.

### BACKGROUND OF THE INVENTION

### Field of the Invention

The present disclosure relates generally systems and methods for attaching a cooler to a computer chip, such as a CPU. More particularly, the present invention relates to a CPU cooler having a novel structure for ensuring optimum contact with the internal heat spreader of a CPU, and method for the same.

### Description of the Related Art

Typical computer systems include heat-generating components that require cooling. Central processing units (CPUs) and graphics processing units (GPUs) are the most common heat generating electrical components in a computing device. Computer cooling systems are used to remove the waste heat produced by CPUs and GPUs and other heat generating computer components.

One type of common CPU cooler is a water based cooler that uses water to remove heat form the CPU. This type of cooler typically has a cold plate as a bottom surface which contacts a computer chip (or metal cover) for transfer of heat away from the computer chip. Most commonly, the fluid is pumped through a reservoir or heat exchanger. An example of such a cooler is shown and described in U.S. Pat. No. 10,524,386, titled WATER COOLER ASSEMBLY AND SYSTEM, the entire contents of each of which are hereby incorporated herein by reference.

Typically, on top of the CPU will be a metal heat spreader, which is typically a conductive plate, such as a nickel-plated copper plate, called an Internal Heat Spreader or IHS. The cooler will be coupled to CPU by clips or a loading mechanism such as an Integrated Loading Mechanism or ILM. The coupling forces push the cooler onto the IHS to create contact with the bottom plate of the cooler, or the cool plate, with the IHS, to optimize conductive heat transfer from the CPU to the cooler. But the compressive forces can deform the cool plate, which is typically made of highly conduct, but soft metal, like copper. The cool plate can deform concavely creating a thermal “hotspot” in the center of the CPU where the base plate of the cooler does not make good contact. Although a conductive paste or jelly can be applied between the cool plate and the IHS, the conductivity of copper far exceeds that of any paste or jelly.

FIG. 8 is a bottom view of a typical CPU cooler or “water-block.” Water-block 800 includes a plastic housing and has a bottom surface 802, a cool plate, designed to remove heat from the CPU, which may have an integrated heat spreader (IHS) on top. The water-block 800 includes an intake and and discharge (not shown) for moving water to and from the cool plate 802 for heat removal. The cool plate should be therefore heat conducted and can be frabicated with heat conductive metals, such as nickel plated copper. A metal clip 808 with fasteners 810 allow the water-block 800 to be secured ontop of a chip (not shown) by fastening it to a motherboard or the like carrying the chip. When installed, the fasteners 810 (which may be, for example, screws) presses the plastic casing down towards the CPU, and the plastic casing of the water-block steps down onto the cool plate 802 in the areas 806 of the screws 804 connecting the housing to the cool plate 802, thereby deforming the cool plate 802 as it is significantly larger than the IHS or the DIE of the CPU. As a result, the cool plate 802 makes poor contact with the CPU or IHS and performance of the cooler is reduced.

FIG. 1A is a simple line drawing of a cross section of a water-block to illustrate further the problem with existing cool plates or water-blocks. Cooler or water-block 100 includes a copper (Cu) base 106 which, in the contact area of the CPU IHS 108, has to be very thin (less than 1 mm) or the thermal resistance increases significantly, making heat removal less efficient. Water-block 100 includes a plastic casing 110 housing the various components of the cooler, which are not shown. The arrows illustrate the mechanical model of force. When installed, the walls of the plastic casing 110 press onto the Cu base 106, which itself is sitting on the IHS 108. This force generates a moment in the Cu base 106, which is thin and soft, and which leads to pressure on the very outer areas of the IHS 108 only. As the DIE (the IC of the CPU (not shown)) is in the center, it is desired to apply pressure in the center to guarantee a good heat transfer from the IHS 108 to the Cu base 106. The opposite result is the case, however, because the Cu base 106 bends upwards and thus opens a gap in the center area between the IHS 108 and the Cu base 106.

Some manufacturers have tried to deal with this problem by creating a convex Cu base surface. For example, the cool plate can be machined to have a convex bottom to shift the contact pressure to the center of the CPU. However, machining adds costs and deformation along the North-South axis and the East-West axis are not the same. Further, this approach only works well and allows high pressure in the center if the Cu base is made thick, which increased the thermal resistance of the cool plate.

Thus, there is a need for a new and improved cooler contact frame that eliminates thermal hot spots and reduces the problems in the prior art with thermal hotspots, and the expense and complexity of cooler installation.

### SUMMARY OF THE INVENTION

The above-described problem costs significant performance in a CPU cooler. The present inventors discovered that by passing the compression charge through the center of the copper base or cool plate to the IHS of the CPU, the thermal resistance can be lowered drastically.

According to embodiments of the present invention, a CPU cooler includes a loading component which distributes compressive forces from the edge of the cooler to a central region of the cool plate to deform the cool plate in a center region so that when the cooler is coupled with the CPU, the cool plate makes optimum contact with the IHS.

According to embodiments of the present invention, an improved cooler is provided for cooling one or more computer processors. The cooler includes a frame, a cool plate having a bottom plate and a plurality of fins forming channels for cooling fluid to pass therethrough; and a bridge spanning the cool plate and being positioned over the plate. The bridge may be convex, on a bottom side, but not necessarily convex as the rubber between bridge and fins could be convex instead, and is adapted to deform the cool plate slightly, so that the bottom plate makes good contact with an IHS of a processor to be cooled.

According to embodiments of the present invention, a method is provided for improving cooling of a computer cooler having a frame coupled with a cool plate, the cool plate having a bottom surface for contacting with a computer component to be cooled and a top surface having a plurality of fins forming channels for cooling fluid to pass therethrough. The method includes providing loading mechanism configured to apply a force from the frame to the cool plate to cause the cool plate to deform toward the bottom surface convexly.

According to embodiments of the present invention, the loading mechanism is a stiff convex-shaped clip.

According to embodiments of the present invention, the clip is formed of metal.

According to embodiments of the present invention, the clip is secured to a top surface of the housing above the cool plate and secured to the edges of the cool plate.

According to embodiments of the present invention, the clip is positioned within said housing above said cool plate.

According to embodiments of the present invention, the loading mechanism is a plastic wall positioned within said housing above said cool plate.

According to embodiments of the present invention, the loading mechanism is a spacer positioned within said housing above said cool plate.

According to embodiments of the present invention, the loading mechanism is tensioned to deform the cool plate toward the bottom surface convexly.

According to embodiments of the present invention, the loading mechanism further comprises a silicone or rubber part.

According to embodiments of the present invention, the silicone or rubber part is a water guide of the cooler for guiding water to and from the fins of the cool plate.

According to embodiments of the present invention, the loading mechanism is spring-like.

According to embodiments of the present invention, an improved computer cooler includes a frame coupled with a cool plate, the cool plate having a bottom surface for contacting with a computer component to be cooled and a top surface having a plurality of fins forming channels for cooling fluid to pass therethrough. The cooler also includes a loading mechanism configured to apply a force from the frame to the cool plate to cause the cool plate to deform toward the bottom surface convexly.

According to embodiments of the present invention, the loading mechanism is a stiff convex-shaped clip.

According to embodiments of the present invention, the clip is formed of metal.

According to embodiments of the present invention, the clip is secured to a top surface of the housing above the cool plate and secured to the edges of the cool plate.

According to embodiments of the present invention, the clip is positioned within said housing above said cool plate.

According to embodiments of the present invention, the loading mechanism is a plastic wall positioned within said housing above said cool plate.

According to embodiments of the present invention, the loading mechanism is a spacer positioned within said housing above said cool plate.

According to embodiments of the present invention, the loading mechanism is tensioned to deform the cool plate toward the bottom surface convexly.

According to embodiments of the present invention, the loading mechanism further comprises a silicone or rubber part.

According to embodiments of the present invention, the silicone or rubber part is a water guide of the cooler for guiding water to and from the fins of the cool plate.

According to embodiments of the present invention, the loading mechanism is spring-like.

According to embodiments of the present invention, a bridge component is provided that is adapted to be coupled with a cooler to deform the cool plate of the cooler slightly, so that the bottom plate makes good contact with an IHS of a processor to be cooled.

According to embodiments of the present invention, the bridge component is an external metal bridge.

According to embodiments of the present invention, the bridge component is an internal structure.

According to embodiments of the present invention, the bridge component is internal plastic bridge.

### BRIEF DESCRIPTION OF DRAWINGS

Embodiments of the present invention are illustrated by way of example with reference to the accompanying drawings, which should not be construed to limit the present disclosure.

FIG. 1 is a simple line diagram of a side view of a water-block.

FIG. 2A is a simple line diagram of a side view of a water-block according to embodiments of the present invention.

FIG. 2B is a simple line diagram of a side view of a water-block according to other embodiments of the present invention.

FIG. 3A shows cross-sectional views of a cooler according to embodiments of the present invention.

FIG. 3B shows cross-sectional views of a cooler according to embodiments of the present invention.

FIG. 3C shows a top view of a cooler according to embodiments of the present invention.

FIGS. 4A and 4B show cross-sectional views of a cooler according to embodiments of the present invention.

FIGS. 5A and 5B show cross-sectional views of a cooler according to embodiments of the present invention.

FIGS. 6A and 6B show expanded views of a cooler according to embodiments of the present invention.

FIG. 7 shows cross-sectional views of a cooler according to embodiments of the present invention.

FIG. 8 is a bottom view of a cooler according to embodiments of the present invention.

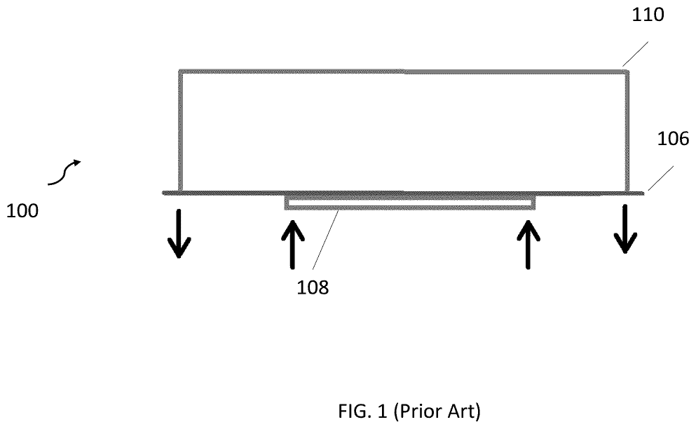

### DETAILED DESCRIPTION OF THE PREFERRED EMBODIMENTS

The following descriptions are presented to enable any person skilled in the art to create and use apparatuses, systems and methods described herein.

A typical CPU or GPU liquid “CPU cooler” or “water-block” has a bottom metal surface (the part that is in contact with the CPU or GPU, transferring the energy from the CPU to the water) typically manufactured of Al or Cu, contacting the CPU, and a cover typically made of plastic. The cool plate has fins on the top designed to transfer energy to water being moved through or over the fins. A pump and a soft molded water channel or water manifold (fabricated from silicon, rubber, soft plastic or the like) guides the water in and out of the fin areas of the cool plate. This silicone part cannot put significant pressure to the center of the cool plate. In order to assure that the parts are connected watertight, there is a seal between plastic housing and metal cool plate.

According to embodiments of the present invention, a compression charge is passed through the center of cool plate of a cooler to the IHS of the CPU to reduce the thermal resistance. According to embodiments of the present invention, this compression charge is provided by added a structural component to the cooler to deliver the charge.

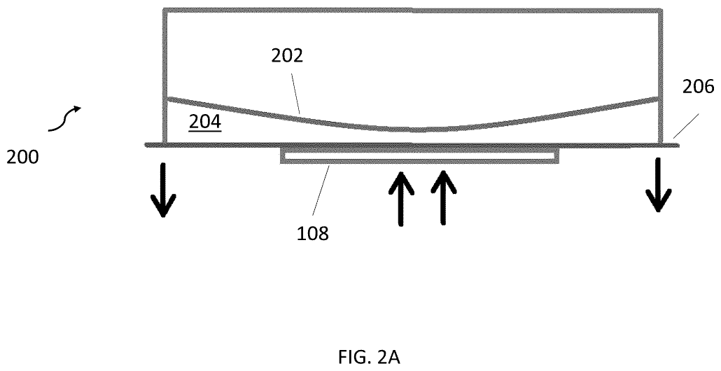

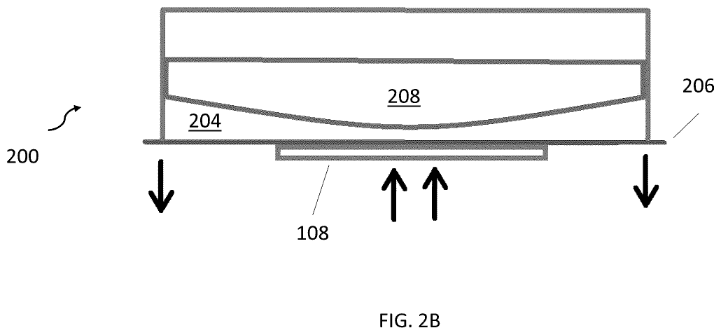

FIG. 2A illustrates a water-block including an internal metal or plastic clip according embodiments of the invention. Water-block 200 is provided with a clip 202, preferably manufactured to be stiff, such as, for example, from metal. The clip 202 is positioned over the silicone rubber molded (or other relatively soft material) water channel or water manifold 204, on top of the cool plate 206, which is preferably thin copper. When the water-block 200 is clamped onto a CPU 108, the clip 202 applies a force through the silicone 204 to the copper base 206 such that the copper base 206 does not deform concave due to the moment load introduced by the IHS and the compression charge is applied to the center of the IHS 108.

FIG. 2B illustrates another water-block according to embodiments of the invention. According embodiments of the invention, the clip 202 may be replaced with a plastic wall 208 (which may be solid or hollow) formed as shown in FIG. 2B. Below the wall 208, there is still silicone or another type of soft (e.g., softer than a typical plastic like ABS) material 204 like in FIG. 2A. When the water-block is clamped onto a CPU 108, the wall 208 applies a force such that the copper base 206 does not face a moment load and the compression charge is applied to the center of the IHS 108. Note, the plastic wall does not need to be curved as shown in FIG. 2B, it could be of any shape as long as it transfers the compression charge to the center of the coldplate.

FIGS. 2A and 2B illustrate merely general examples of the invention. Further, while FIGS. 2A and 2B illustrate examples of internal clips or bridges, external clips or bridges are also contemplated. According to embodiments of the invention, using a combination of a stiff component (bridge, clip, spacer, wall, etc.) with a soft component (e.g., silicone manifold or water channel), a spring-loaded-like mechanism is created. The stiffness provides the initial force, while the soft material allows for deformation and compliance when opposing forces are applied. Therefore, when the cooler is assembled, the cool plate will deform outward, convexly, but can deform back to flat or near flat when the cooler is installed onto a CPU.

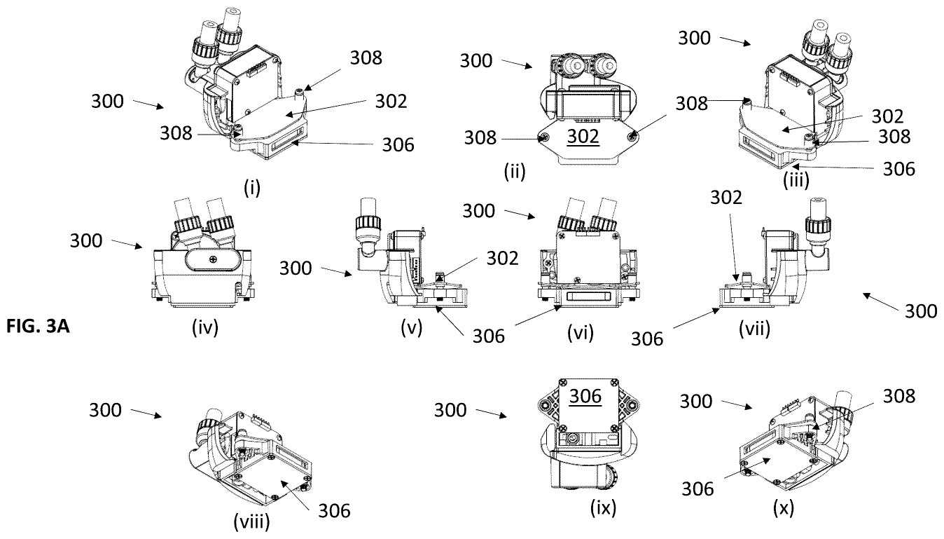

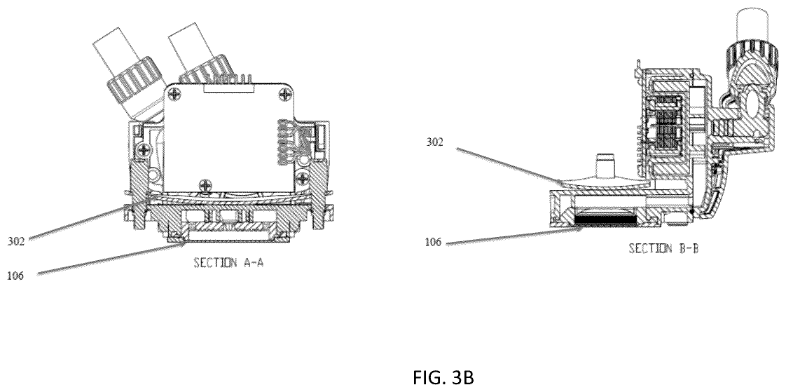

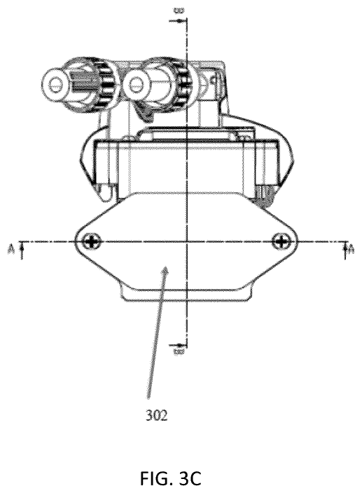

FIG. 3A includes multiple (10) views (i-x) of a water-block 300 having an external metal clip 302 secured thereto according to embodiments of the present invention. FIGS. 3A(i) and (iii) are top perspective views. FIG. 3A(ii) is a top view. FIG. 3A(viii) and (x) are bottom perspective views. FIG. 3A(v) and (vii) are side views. FIG. 3A(vi) is a front view, and (iv) is a rear view. As can be seen, the clip 302 is positioned over the portion of the water-block 300 that includes the cool plate 306. Clip 302 is secured with fasteners 308 to the housing of water-block 300.

FIG. 3B is a top view of the water-block 300 showing cross section axes AA and BB.

FIG. 3C shows cross-sectional views A-A (top) and B-B (bottom) of the water-block 300 having the external metal clip 302 before installation of the clip 302 to the cool plate 306, according to embodiments of the present invention. As shown, water-block 300 has positioned to the top of the cooler, a metal clip 302 by fasteners 308. The clip 302 is preferably made of a stiff material, such as metal. As shown in the bottom of FIG. 3C, the clip 302 sits on top of the cool plate 306, which has a manifold 310 onto of the cool plate 306 for moving water to and from the cool plate 306 for cooling. As shown, when fasteners are not tensioned, the Cu plate 306 is not deformed, but rather flat.

FIG. 3D shows cross-sectional views A-A (top) and B-B (bottom) of the water-block 300 having the external metal clip 302 after tensioning of the metal clip 302 according to embodiments of the present invention.

It is important that pressure is provided at the center of the clip 302, to force it onto the fins and not to the sides of the cool plate 306. As shown, two fasteners 308 are used to secure the clip 302, but other arrangements can be used. When secured and the fasteners 308 are tensioned, the clip 302 applies pressure the plastic cover 312, which step down via walls or fins onto the silicone/rubber seal 310, which press onto the fins of the copper plate 306. Pressure should be applied to the center onto the fins, which is intended to contact with the hottest part of the CPU. By applying force onto the plastic 312, the charge is transferred onto the copper plate 306 and from there onto the center of the IHS.

FIGS. 3C and 3D relate to assembly of the cooler, not mounting the cooler on the CPU. As shown, after assembly and tensioning of the clip 302, the cool plate 306 will be slightly bent. Once fastened, the cool plate 306 will deform, but when the water block is installed over a CPU, it will flatten it. Accordingly, when installed on a CPU, the present invention assures that the pressure in the center of the cooler will cause a good contact at the center of the CPU.

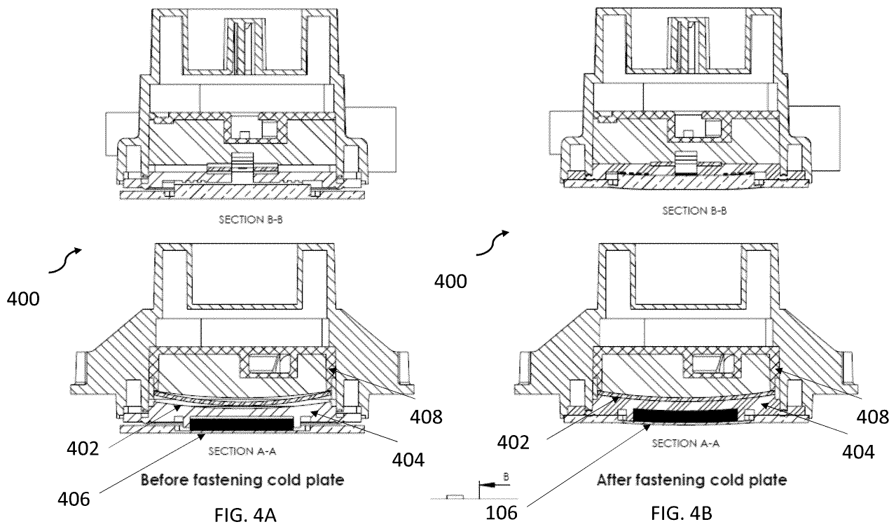

FIGS. 4A-B illustrate a water-block with an internal clip according to embodiments of the present invention. FIGS. 4A-B are cross-sectional views of water-block 400 before and after complete assembly, respective. As shown, water-block 400 includes an internal clip 402 positioned over the silicone manifold 404 of the cooler 400. The clip 402 is preferably formed of a stiff material, such as metal, and secured to the housing 408 of the cooler 400.

The cooler 400 is designed such that before fastening of the internal clip 402, there is a slight gap between the clip 402 and the lower silicone part 404 which sits on top of the Cu plate 406. This gap is smaller in the center compared to the outside. Once screws fixing the Cu plate 406 onto the plastic housing of the water-block are fastened, the gap in the outer areas of the clip 402 and the metal clip 402 are closing and in the center, there is a conflict between clip and silicone part 404 between clip 402 and Cu fins (above 406). This deforms clip 402 as well as cu plate 406 as seen in FIG. 4B. Installing it on a CPU, the Cu base 106 will deform back flat, deforming the internal metal clip 402 further and guaranteeing that a large portion of the compression charge goes through the center, thereby improving contact. The metal clip 402 can of course be built of another material like plastics or composite materials.

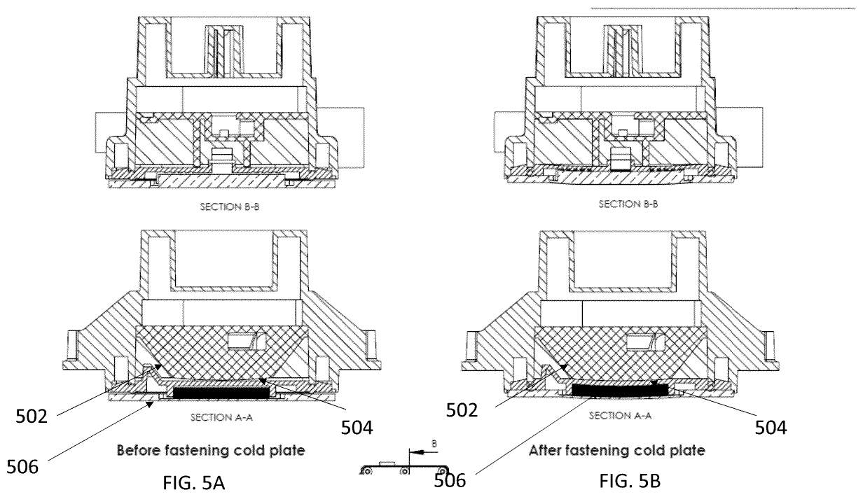

FIGS. 5A and 5B show a water-block with an internal plastic wall 502 according to embodiments of the present invention. FIGS. 5A-B are cross-sectional views of water-block 500 before and after complete assembly, respective. Plastic walls 502 create pressure on the rubber part 504 between fins and walls after fasting the screws fixing the Cu plate 506 onto the plastic housing 510. Preferably, there are two walls, one on either side of the water in or out of the center. Also preferably, the walls are slightly curved so that they create higher pressure in the center. But alternatively the thickness of the rubber of the manifold could be higher in the center. The pressure on top of the fins lead to a deformation of the Cu base 506 which will become flat again after installation on a CPU, guaranteeing that there is a higher pressure in the center rather than lower.

In other embodiments, other structures are contemplated that elevate pressure on top of the fins and thus guarantee that the Cu base being larger than the IHS of the CPU does not end up in a concave shape after installation but rather being flat or slightly convex depending on the CPUs IHS surface (the AMD is typically flat and the Intel IHS is often concave after fastening the ILM).

The copper cool plate should designed such that it is allowed to deform enough, but also allowed to flatten out when pressed onto the CPU. The skilled person should understand that there is a certain level of stiffness that is desired, and it should be applied above the rubber/copper layer of the cooler. The rubber will distribute the forces more evenly and allow the soft, very thin cool plate to go flat.

In some embodiments, the cool plate of the water-block is about 1 mil thick, but the fins are 3 mils thick, with only 2 mil of space between them. The fins help distribute the forces from the silicon. Preferably, there is a minimum of 0.5 mm thickness of the Cu base and a fin pitch of minimum 0.2 mm, fin height of 2.5 mm.

According to embodiments of the invention, a bridge is provided that distributes the compressive forces from the perimeter of the cooler where the cooler is connected to the board via a clip or ILM or bolts or other fasteners. The bridge should go around injector holes and discharge holes of the internal silicone manifold covering the fins.

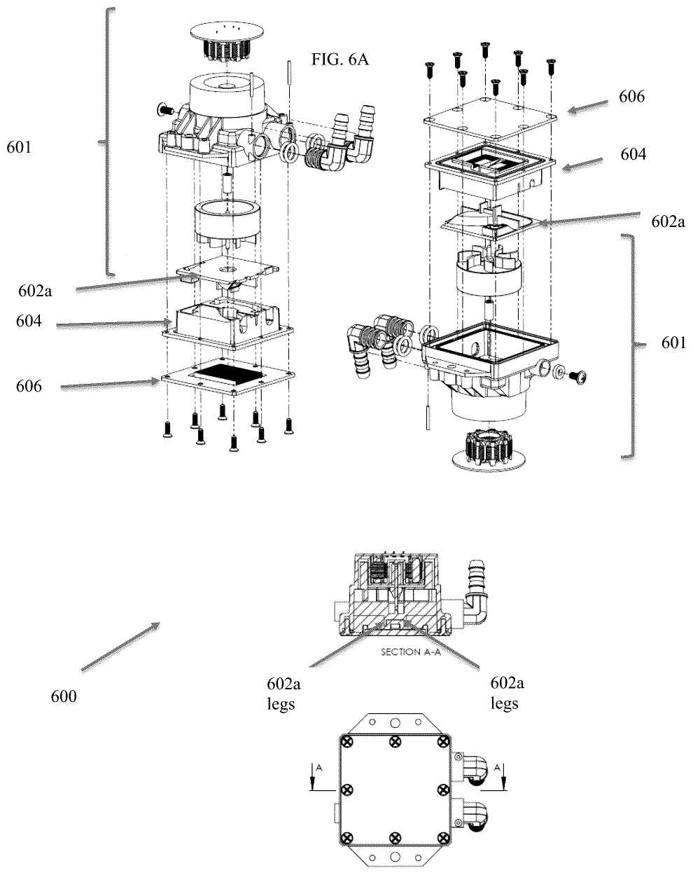

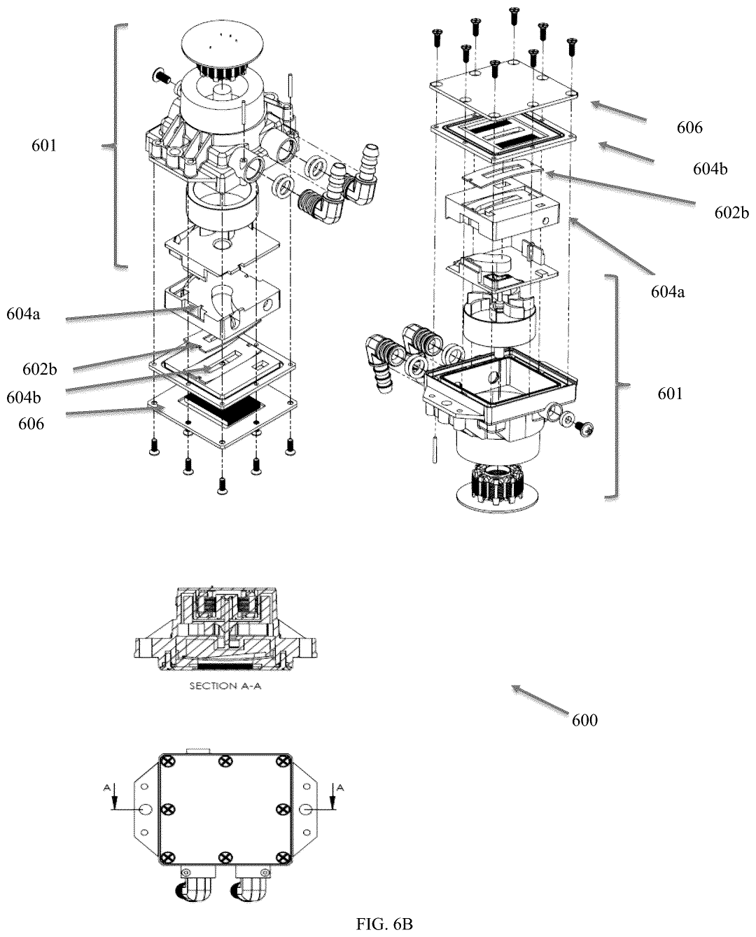

Referring to FIGS. 6A and 6B, expanded assembly drawings illustrate a water-block according to embodiments of the present invention. FIG. 6A shows the water-block in an exploded view. As shown, the cooler assembly 600 includes a pump assembly 601 which pumps cooling fluid to and from the cool plate 606 via a manifold 604 that channels the fluid into and away from fins formed on top in the cool plate 606. On the right-hand side, the same assembly 600 is inverted to show details hidden in the view on the left side. The skilled person will readily understand the structure of the cooler form FIG. 6A, including the various structural components and fasteners. A bridge 602a is provided for delivering compressive forces to the cool plate 606 through the manifold 604. When assembled, the pump 601 applies downward force on the top of bridge 602, which applies force through manifold 604. As shown, bridge 602a has 2 step-down legs and the manifold includes matching cavity/counter-pieces that allows water flow, but otherwise fills an empty space. Each leg of bridge 602a should span more than one fin, so the fins should be perpendicular to the fins to help distribute the load. The bridge 602a should preferably be designed to have most of the pressure in the center of the CPU. The skilled person will understand how to size and position the bridge 602a based on the thickness of the plate, size of the fins and so forth.

FIG. 6B shows a similar water-block including an internal clip 602b rather than a bridge. As shown, the manifold or water guide maybe be formed in two sections (604a,b) to deliver fluid to and from the cool plate 606. The clip 602b is positioned between 604a and 604b to apply pressure to the central region of the cool plate 606 in order to slightly deform the cool plate 606 outward convexly. Therefore, the water guide can be shaped to hold the clip 602b. When assembled, the pump 601 applies downward force on the top 604a of the water guide.

As explained herein, when attached to a processor to be cooled, the cool plate 606 will flatten onto the IHS and make good contact therewith for cooling.

The clip 602 is preferably stiff and may be manufactured from metal. As shown, the clip is convex so as to apply a force to the cool plate 606 to cause it to deform convexly so that the best contact with a CPU is made in the center of the cool plate 606. As described above, the thickness of the fins and plate can be selected to allow for deformation and also to all the cool plate to flatten when pressed against the CPU.

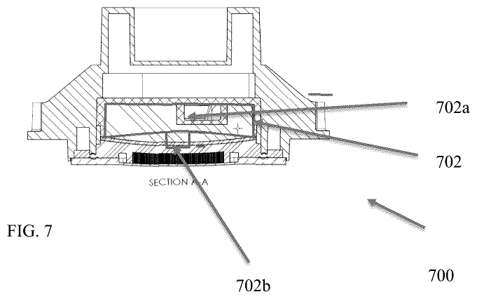

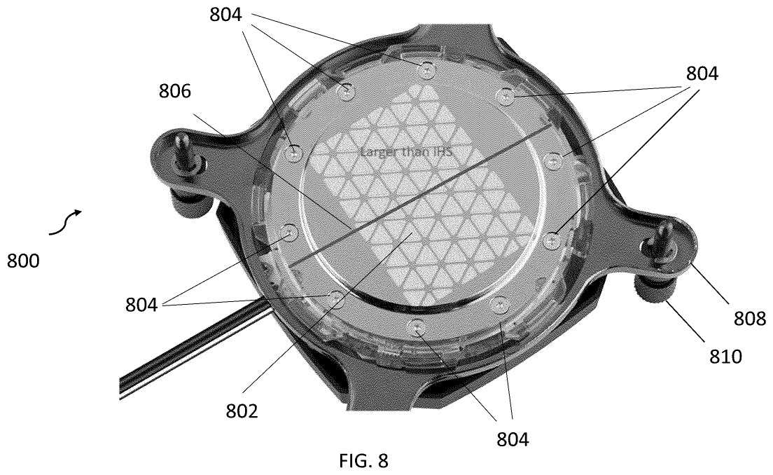

FIG. 7 shows a cross section of a cooler having a plastic bridge 702 having an upper section 702a and spacer region 702b, which distributes the compressive forces to the central region of the cool-plate. As illustrated here, and to be understood, is that the bridge 702 is not limited to being convex so long as sufficient compressive forces are applied to the center region of the cool-plate. Here the upper section 702a is actually concave but the spacer 702b provides compressive forces to the center of the cool-plate below.

Various modifications to the example embodiments will be readily apparent to those skilled in the art, and the generic principles defined herein may be applied to other embodiments and applications without departing from the spirit and scope of the invention. For example, the specifications for a CPU may require a different socket shape, different height restrictions, or different components to be connected. Thus the mounting region may be a different shape, at a difference height, at the same level or even lower than the CPU top surface, etc. requiring modifications to the disclosed structure. Such modifications are clearly contemplated as part of the present invention.

According to some embodiments, the clip can be fairly independent of the housing and simply press in the center of the housing. Through a spacer, the application charge may be transferred to the fins.

Materials may vary based on the compression charge necessary and the design of the cooler.

Moreover, in this description, numerous details are set forth for the purpose of explanation. However, one of ordinary skill in the art will realize that the invention may be practiced without the use of these specific details. In other instances, well-known structures and processes are shown in block diagram form in order not to obscure the description of the invention with unnecessary detail. Thus, the present disclosure is not intended to be limited to the embodiments shown, but is to be accorded the widest scope consistent with the principles and features disclosed herein.

In describing exemplary embodiments, specific terminology is used for the sake of clarity. For purposes of description, each specific term is intended to at least include all technical and functional equivalents that operate in a similar manner to accomplish a similar purpose. Additionally, in some instances where a particular exemplary embodiment includes a plurality of system elements, device components or method steps, those elements, components or steps may be replaced with a single element, component or step. Likewise, a single element, component or step may be replaced with a plurality of elements, components or steps that serve the same purpose. Moreover, while exemplary embodiments have been shown and described with references to particular embodiments thereof, those of ordinary skill in the art will understand that various substitutions and alterations in form and detail may be made therein without departing from the scope of the invention. Further still, other embodiments, functions and advantages are also within the scope of the invention.

What is claimed is:

1. A method for improving cooling of a computer cooler having a frame coupled with a cool plate, the cool plate having a bottom surface for contacting with a computer component to be cooled and a top surface having a plurality of fins forming channels for cooling fluid to pass therethrough, the method comprising a step of:
providing loading mechanism configured to apply a force from the frame to the cool plate to cause the cool plate to prevent the cool plate from deforming concavely when pressed on a IHS of a CPU.

2. The method of claim 1, wherein the loading mechanism is a stiff convex or concave shaped clip.

3. The method of claim 2, wherein the clip is formed of metal.

4. The method of claim 3, wherein the clip is secured to a top surface of the housing above the cool plate and secured to the edges of the cool plate.

5. The method of claim 3, wherein the clip is positioned within said housing above said cool plate.

6. The method of claim 1, wherein the loading mechanism is a plastic wall positioned within said housing above said cool plate.

7. The method of claim 1, wherein the loading mechanism is a spacer positioned within said housing above said cool plate.

8. The method of claim 1, wherein the loading mechanism is tensioned to deform the cool plate toward the bottom surface convexly.

9. The method of claim 1, wherein the loading mechanism further comprises a silicone, rubber or plastic part.

10. The method of claim 9, wherein silicone, rubber or plastic part is a water guide of the cooler for guiding water to and from the fins of the cool plate.

11. The method of claim 1, wherein the loading mechanism is spring-like.

12. An improved computer cooler, comprising:
a frame coupled with a cool plate, the cool plate having a bottom surface for contacting with a computer component to be cooled and a top surface having a plurality of fins forming channels for cooling fluid to pass therethrough; and
a loading mechanism configured to apply a force from the frame to the cool plate to cause the cool plate to deform toward the bottom surface convexly.

13. The cooler of claim 12, wherein the loading mechanism is a stiff convex or concave shaped clip.

14. The cooler of claim 13, wherein the clip is formed of metal.

15. The cooler of claim 14, wherein the clip is secured to a top surface of the housing above the cool plate and secured to the edges of the cool plate.

16. The cooler of claim 14, wherein the clip is positioned within said housing above said cool plate.

17. The cooler of claim 12, wherein the loading mechanism is a plastic wall positioned within said housing above said cool plate.

18. The cooler of claim 12, wherein the loading mechanism is a spacer positioned within said housing above said cool plate.

19. The cooler of claim 12, wherein the loading mechanism is tensioned to deform the cool plate toward the bottom surface convexly.

20. The cooler of claim 12, wherein the loading mechanism further comprises a silicone, rubber or plastic part.

21. The cooler of claim 20, wherein the silicone, rubber or plastic part is a water guide of the cooler for guiding water to and from the fins of the cool plate.

22. The method of claim 12, wherein the loading mechanism is spring-like.
